(19) United States
(12) Patent Application Publication
(10) Pub. No.: US 2009/0284893 A1
(43) Pub. Date: Nov. 19, 2009

(54) Electrostatic chuck

(75) Inventors: Masami Ando, Fukuoka-ken (JP); Toshihiro Aoshima, Fukuoka-ken (JP)

Correspondence Address: CARRIER BLACKMAN AND ASSOCIATES, 43440 WEST TEN MILE ROAD, EATON CENTER, NOVI, MI, 48375, US

(73) Assignee: Toto Ltd., Kitakyushu-shi (JP)

(21) Appl. No.: 12/454,030

(22) Filed: May 11, 2009

Related U.S. Application Data
(60) Provisional application No. 61/080,688, filed on Jul. 15, 2008.

(30) Foreign Application Priority Data
May 13, 2008 (JP) 2008-125570

(51) Int. Cl. H01L 21/683

(52) U.S. Cl. 361/234

(57) ABSTRACT

An electrostatic chuck of the invention includes a ceramic dielectric made of a sintered body containing alumina and titanium oxide, with maximum particle size of segregation bodies of titanium compounds being smaller than average particle size of alumina, the ceramic dielectric having a volume resistivity of 10⁸ Ωcm or more and 10¹³ Ωcm or less at room temperature.

### CROSS-REFERENCE TO RELATED APPLICATIONS

This application is based upon and claims the benefits of priorities from the prior Japanese Patent Application No. 2008-125570, filed on May 13, 2008 and the prior U.S. provisional Patent Application No. 61/080,688, filed on Jul. 15, 2008; the entire contents of which are incorporated herein by reference.

### BACKGROUND OF THE INVENTION

1. Field of the Invention

This invention relates generally to an electrostatic chuck.

2. Background Art

An electrostatic chuck is used as a means for attracting and holding a workpiece, such as a semiconductor wafer and a glass substrate, in a plasma processing chamber for etching, CVD, sputtering, ion implantation, and ashing.

There are two types of electrostatic chucks: those using the Johnsen-Rahbek force and those using the Coulomb force. Electrostatic chucks using the Johnsen-Rahbek force are used in applications requiring large attracting force. To develop such electrostatic attracting force by the Johnsen-Rahbek force, the volume resistivity of the dielectric needs to be controlled in a range of 10⁸ Ωcm or more and 10¹³ Ωcm or less.

With regard to controlling the volume resistivity of the dielectric in a range of 10⁸ Ωcm or more and 10¹³ Ωcm or less, ceramic dielectrics of alumina with titanium oxide added thereto are disclosed in Patent Documents 1 to 5.

After plasma processing, residues and products from the semiconductor wafer and the deposited film are attached to the chamber inner surface. With the repetition of plasma processing, residues and products are gradually piled up. They are eventually flaked off from the chamber inner surface and attached to the surface of a workpiece, such as a semiconductor wafer and a glass substrate, causing decreased yield.

In this regard, conventionally, the inside of the chamber is regularly cleaned by plasma to remove residues and products attached to the chamber inner surface. In the past, to prevent the surface of the electrostatic chuck from being exposed to plasma, cleaning was performed with the surface of the electrostatic chuck covered with a dummy wafer. However, the recent trend in the industry is the so-called waterless plasma cleaning in which, to reduce tact time to improve production efficiency, cleaning is performed by directly exposing the surface of the electrostatic chuck to a cleaning plasma of O₂ gas, CF₄ gas and the like without covering the surface of the electrostatic chuck with a dummy wafer.

Widely-used electrostatic chucks using the Johnsen-Rahbek force, which consist primarily of alumina, are composed of very large alumina particles having an average particle size of 5 to 100 μm. Hence, the aforementioned waterless plasma cleaning increases surface roughness by detachment of ceramic surface particles and corrosion of grain boundaries. This results in problems such as decreased electrostatic attracting force, increased amount of gas leakage through the seal ring, and decreased thermal conductivity at the solid contact interface with the semiconductor wafer, forcing the electrostatic chuck to be replaced in a short period of time.

To solve these problems, Patent Document 5 discloses an electrostatic chuck of sintered alumina with a slight amount of titanium oxide added thereto in which the average particle size of alumina is reduced to 2 μm or less. However, this technique also has the problem of increased variation in surface roughness caused by plasma irradiation if the added titanium oxide forms segregation bodies of titanium compounds.

Patent Document JP-A-62-094953

Patent Document JP-A-2-206147

Patent Document JP-A-3-147843

Patent Document JP-A-3-204924

Patent Document JP-A-2006-049356

### SUMMARY OF THE INVENTION

According to an aspect of the invention, there is provided an electrostatic chuck including a ceramic dielectric made of a sintered body containing alumina and titanium oxide, with maximum particle size of segregation bodies of titanium compounds being smaller than average particle size of alumina, the ceramic dielectric having a volume resistivity of 10⁸ Ωcm or more and 10¹³ Ωcm or less at room temperature.

### BRIEF DESCRIPTION OF THE DRAWINGS

FIG. 1 is a schematic cross-sectional view for illustrating a electrostatic chuck according to an embodiment of the invention.

FIG. 2 is a cross-sectional SEM micrograph of a ceramic dielectric illustrated in Example 4.

FIG. 3 is a cross-sectional SEM micrograph of a ceramic dielectric illustrated in Comparative example 2.

### DETAILED DESCRIPTION OF THE INVENTION

A first aspect of the invention is an electrostatic chuck including a ceramic dielectric made of a sintered body containing alumina and titanium oxide, with maximum particle size of segregation bodies of titanium compounds being smaller than average particle size of alumina, the ceramic dielectric having a volume resistivity of 10⁸ Ωcm or more and 10¹³ Ωcm or less at room temperature.

In this electrostatic chuck, the maximum particle size of the segregation bodies of titanium compounds is smaller than the average particle size of alumina. This serves to reduce variation in surface roughness caused by plasma irradiation. Hence, the electrostatic chuck also has small variation in characteristics, and can be used for a longer period of time in a plasma processing chamber. Furthermore, the volume resistivity of the aforementioned dielectric is in a range of 10⁸ Ωcm or more and 10¹³ Ωcm or less at room temperature, realizing an electrostatic chuck using the Johnsen-Rahbek force.

A second aspect of the invention is an electrostatic chuck according to the first aspect of the invention wherein the maximum particle size of the segregation bodies of titanium compounds is 2 μm or less.

Decrease in the maximum particle size of the segregation bodies of titanium compounds serves to reduce variation in surface roughness caused by plasma irradiation. Hence, the electrostatic chuck also has small variation in characteristics, and can be used for a longer period of time in a plasma processing chamber.

A third aspect of the invention is an electrostatic chuck according to the first or second aspect of the invention wherein the ceramic dielectric has a bulk density of 3.97 g/cm³ or more.

Increase in bulk density leads to a dense ceramic dielectric with decreased pores, which serves to reduce variation in surface roughness caused by plasma irradiation.

In this description, the ceramic dielectric containing alumina and titanium oxide refers to a sintered body obtained by shaping a powder mixture of alumina and titanium oxide followed by firing, which is a sintered ceramic composed of alumina in the form of corundum crystal particles and titanium compounds.

To realize a volume resistivity of approximately 10¹³ Ωcm, the amount of titanium oxide added to alumina is preferably 0.1 wt % or more, and more preferably 0.2 wt % or more. On the other hand, excessive addition of titanium oxide forms titanium segregation bodies, causing decreased plasma resistance. Hence, the amount of added titanium oxide is preferably less than 1 wt %.

The segregation bodies of titanium compounds refer to segregation bodies of particles composed of titanium oxide and compounds of titanium oxide and aluminum oxide, such as aluminum titanate, present in the aforementioned dielectric, and can be confirmed by cutting and polishing the aforementioned dielectric and observing the section by a scanning electron microscope (SEM).

The maximum particle size of the segregation bodies of titanium compounds refers to the particle size corresponding to 99% cumulative frequency of the measured maximum length of the particle size for 100 or more segregated particles observed in the scanning electron micrograph of the aforementioned section. It was set to zero when no segregation body was observed. The observation magnification of the aforementioned scanning electron microscope was 4000, and the micrograph was taken by adjusting the number of fields of view so that 100 or more segregation bodies are observed.

The surface roughness Ra refers to the center-line average surface roughness specified in the Japanese Industrial Standard (JIS B 0601).

The bulk density refers to a value measured by the Archimedes method specified in the Japanese Industrial Standard (JIS R 1634). In the measurement, the water saturation method was the vacuum method, using distilled water as the solvent.

The volume resistivity refers to a value measured by using the three-terminal method specified in the Japanese Industrial Standard (JIS C 2141:1992, Testing methods of ceramic insulators for electrical and electronic applications). The measurement was performed at room temperature (25° C.).

The particle size of the raw material was measured by the following method. The average particle size of alumina was measured by using a laser diffraction-based particle size distribution analyzer (Microtrac MT3000 by Nikkiso Co., Ltd.). Here, the measurement was performed after application of a supersonic homogenizer for 15 to 30 minutes to disaggregate and disperse aggregated particles in the raw material.

On the other hand, the average particle size of titanium oxide was the cumulant average particle size determined by a light scattering photometer (FPAR-1000 by Otsuka Electronics Co., Ltd.).

The average particle size of the alumina particle of a fired body was calculated by the planimetric method. The sample was mirror-polished, and then thermally etched at a suitable temperature in the ambient atmosphere to make particles visible. Then, the measurement was performed using an image observed by a scanning electron microscope (SEM).

An embodiment of the invention will now be illustrated with reference to the drawings.

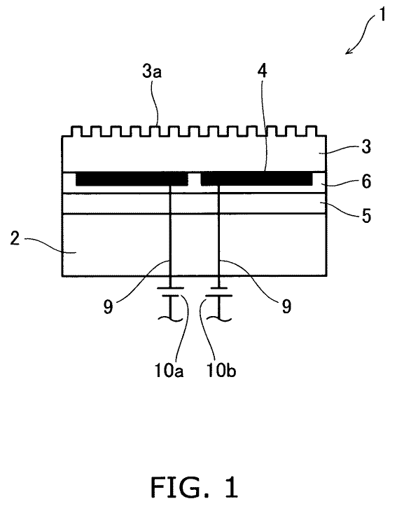

FIG. 1 is a schematic cross-sectional view for illustrating an electrostatic chuck according to the embodiment of the invention.

As shown in FIG. 1, the electrostatic chuck 1 includes a base 2, a ceramic dielectric 3, and electrodes 4.

An insulator layer 5 illustratively made of an inorganic material is provided on one major surface of the base 2 illustratively made of a metal.

Furthermore, protrusions 3a are formed at a major surface of the ceramic dielectric 3 on which a workpiece, such as a semiconductor wafer, is to be mounted. The top surface of the protrusions 3a serves as a mounting surface when a workpiece, such as a semiconductor wafer, is mounted.

The electrodes 4 are provided on a major surface of the ceramic dielectric 3 opposite to the major surface including the protrusions 3a.

The side of the ceramic dielectric 3 provided with the electrodes 4 is bonded to the side of the base 2 provided with the insulator layer 5 by using an insulating adhesive. This insulating adhesive is cured into a bonding layer 6.

The electrodes 4 are connected to a power supply 10a and a power supply 10b by electric wires 9. The electric wires 9 pass through the base 2, but are insulated from the base 2.

What is illustrated in FIG. 1 is a so-called bipolar electrostatic chuck in which a positive and a negative electrode are adjacently formed on the ceramic dielectric 3. However, the electrostatic chuck is not limited thereto, but may be a so-called unipolar electrostatic chuck in which one electrode is provided on the ceramic dielectric 3, or may be tripolar or other multipolar one. Furthermore, the number of electrodes and their layout can be suitably modified.

Here, in the ceramic dielectric 3 containing alumina and titanium oxide provided in the electrostatic chuck 1, the maximum particle size of the segregation bodies of titanium compounds is preferably smaller than the average particle size of alumina. Titanium compounds are less resistant to plasma than alumina and easily eroded by plasma irradiation to form a recess. Hence, if the segregation bodies of titanium compounds are smaller in size than alumina particles, variation in surface roughness caused by plasma irradiation can be significantly reduced.

Furthermore, in the ceramic dielectric 3 containing alumina and titanium oxide provided in the electrostatic chuck 1, the maximum particle size of the segregation bodies of titanium compounds is preferably 2 μm or less, and more preferably 1.3 μm or less. Titanium compounds are less resistant to plasma than alumina and easily eroded by plasma irradiation to form a recess. Hence, if the segregation bodies of titanium compounds are reduced in size, variation in surface roughness caused by plasma irradiation can be significantly reduced. Here, the lower limit of the maximum particle size of the segregation bodies of titanium compounds is preferably 0.1 μm.

Next, a method for manufacturing the electrostatic chuck 1 according to this embodiment is illustrated.

First, alumina and titanium oxide are prepared as a raw material. The alumina and titanium oxide used are preferably fine-grained. The alumina powder used has an average particle size of 0.3 μm or less, and more preferably 0.2 μm or less. On the other hand, the titanium oxide powder used has an average particle size of 0.1 μm or less, and more preferably 0.05 μm or less. By using fine-grained powder as a raw material, good dispersion is achieved, and segregation bodies of titanium compounds having a large particle size are less likely to occur.

The lower limit of the average particle size of alumina powder is preferably 10 nm. The lower limit of the average particle size of titanium oxide powder is preferably 5 nm.

### (Slurry Preparation, Granulation, Green Processing)

The aforementioned raw material is weighed to a prescribed amount. Furthermore, a dispersant, binder, and release agent are added thereto, and crushed, stirred, and mixed by a ball mill. Preferably, the mixing process uses ion-exchanged water or the like to avoid contamination by impurities. After mixing, a spray dryer is used for granulation, and the granulated powder can be press molded into a green compact. Furthermore, preferably, the aforementioned green compact is CIP molded. CIP molding serves to increase the density of the green compact, and increase the density of the fired body. In the embodiment of the invention, molding is not limited to dry molding, but the green compact can also be obtained by molding processes such as extrusion molding, injection molding, sheet molding, casting, and gel cast molding.

### (Firing)

The ceramic dielectric 3 can be fabricated by firing the aforementioned green compact in a reducing atmosphere of nitrogen and hydrogen gas. Reduction firing results in titanium oxide with non-stoichiometric composition so that the volume resistivity can be controlled. The firing temperature is preferably in the range of 1150° C. or more and 1350° C. or less, and more preferably in the range of 1150° C. or more and 1200° C. or less. Firing at low temperature can prevent growth of alumina particles, also prevent growth of segregated titanium compounds, and the maximum particle size thereof can be decreased. Hence, the average particle size of the alumina particles is preferably 5 μm or less, and more preferably 2 μm or less. Here, the lower limit of the average particle size of the alumina particles is preferably 10 nm.

Furthermore, the retention time of firing at the highest temperature is preferably 2 hours or more, and more preferably 4 hours or more, to stabilize the material property values of the fired body.

The resulting fired body is preferably subjected to HIP processing. Thus, a dense ceramic dielectric 3 can be realized.

### (Electrode Fabrication)

After the surface of the ceramic dielectric 3 is ground, a conductive film of TiC, Ti or the like can be formed on one side by CVD or PVD, and shaped by sandblasting or etching into electrodes 4 having a prescribed configuration.

### (Bonding)

The ceramic dielectric 3 with the electrodes 4 formed thereon is bonded to the base 2 having a major surface on which the insulator layer 5 is previously formed by ceramic spraying.

Here, the side of the base 2 provided with the insulator layer 5 is opposed to the side of the ceramic dielectric 3 provided with the electrodes 4, and they are bonded using an insulating adhesive. This insulating adhesive is cured into a bonding layer 6.

In ceramic spraying, ceramics such as alumina and yttria are preferably used.

### (Surface Patterning)

After the ceramic dielectric 3 bonded to the base 2 is ground to a prescribed thickness, protrusions 3a having a prescribed size and height are formed at the surface by sandblasting.

The foregoing process allows the volume resistivity of the ceramic dielectric 3 to be in a range of 10⁸ Ωcm or more and 10¹³ Ωcm or less at room temperature. Thus, because the Johnsen-Rahbek force can be used, a very large attracting force can be developed. Furthermore, an electrostatic chuck 1 including protrusions 3a at the surface can be realized.

### EXAMPLES

In the following, the ceramic dielectric 3 is further illustrated with reference to examples.

Alumina (average particle size 0.15 μm, purity 99.99% or more) and titanium oxide (average particle size 0.032 μm) were prepared as a raw material. The amount of added titanium oxide was 0.2 wt % or more and 0.8 wt % or less. The raw material, with a dispersant, binder, and release agent added thereto, was crushed, stirred, and mixed by a ball mill. After mixing, a spray dryer was used for granulation. The granulated powder was press molded, and then CIP molded. The resulting compact was fired for 4 hours at 1150° C. or more and 1350° C. or less in a reducing atmosphere of nitrogen and hydrogen gas. Furthermore, it was HIP processed in Ar gas at 1500 atmospheres, and 1130° C. or more and 1300° C. or less.

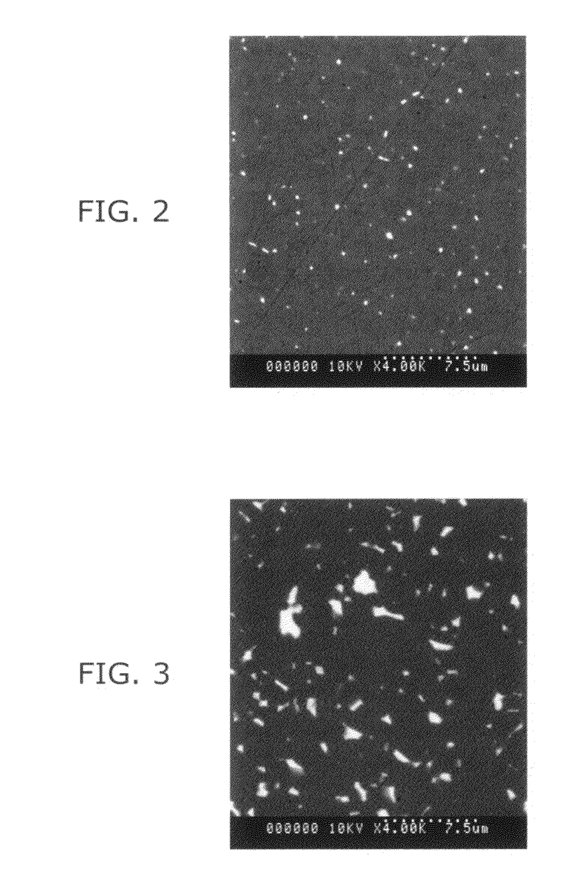

TABLE 1 shows the bulk density and volume resistivity of the resulting ceramic dielectric 3, the maximum particle size of segregation bodies of titanium compounds, and the average particle size of alumina. FIG. 2 shows a cross-sectional SEM micrograph of the ceramic dielectric 3 of Example 4. The white portion in the micrograph indicates the segregation bodies of titanium compounds.

TABLE 1

| | | | | Maximum particle size | | Surface roughness |
|---|---|---|---|---|---|---|
| | Added | Volume | Bulk | of segregation bodies | Average particle | Ra after plasma |
| | TiO₂ | resistivity | density | of titanium compounds | size of alumina | irradiation |
| | (wt %) | (Ωcm) | (g/cm³) | (μm) | (μm) | (μm) |
| Ex 1 | 0.2 | 10^{10.4} | 3.98 | 0.8 | 1.3 | 0.09 |
| Ex 2 | 0.4 | 10^{9.4} | 3.98 | 1.3 | 1.5 | 0.14 |
| Ex 3 | 0.5 | 10^{8.8} | 3.98 | 1.1 | 1.5 | 0.12 |
| Ex 4 | 0.8 | 10^{8.6} | 3.97 | 0.8 | 2.0 | 0.13 |
| Comp 1 | 1 | 10^{8.6} | 3.98 | 2.4 | 2.2 | 0.30 |
| Comp 2 | 5 | 10^{8.4} | 3.98 | 4.1 | 2.2 | 0.42 |

Furthermore, the sample with the surface lapped was irradiated with plasma, and variation in surface roughness Ra was measured. The surface roughness Ra in the initial state of the sample was 0.01 μm or less. Plasma irradiation was performed by a reactive ion etching system (DEA-506 by ANELVA Corporation) using an etching gas of CF₄ (40 sccm)+O₂ (10 sccm) at 1000 W for 30 hours. The surface roughness Ra after plasma irradiation is also shown in TABLE 1.

In Examples 1 to 4 (Ex 1 to 4), ceramic dielectrics 3 having a volume resistivity of 10⁸ Ωcm or more and 10¹³ Ωcm or less, suitable to using the Johnsen-Rahbek force, were obtained. Furthermore, in these ceramic dielectrics 3, the maximum particle size of the segregation bodies of titanium compounds was smaller than the average particle size of alumina, and the maximum particle size of the segregation bodies of titanium compounds was 2 μm or less. The surface roughness Ra after plasma irradiation was 0.15 μm or less, indicating small variation in surface roughness.

In Comparative example 1 (Comp 1), the amount of added titanium oxide was 1 wt %. The maximum particle size of the segregation bodies of titanium compounds was larger than the average particle size of alumina, and the maximum particle size of the segregation bodies of titanium compounds was 2.4 μm. The surface roughness Ra after plasma irradiation significantly increased to 0.30 μm.

In Comparative example 2 (Comp 2), the amount of added titanium oxide was 5 wt %. FIG. 3 shows a cross-sectional SEM micrograph thereof. It indicates the presence of large segregation bodies of titanium compounds. The maximum particle size of the segregation bodies of titanium compounds was larger than the average particle size of alumina, and the maximum particle size of the segregation bodies of titanium compounds was 4.1 μm. The surface roughness Ra after plasma irradiation significantly increased to 0.42 μm.

From the foregoing results, if the maximum particle size of the segregation bodies of titanium compounds is smaller than the average particle size of alumina, and the maximum particle size of the segregation bodies of titanium compounds is 2 μm or less, then variation in surface roughness can be reduced even in plasma irradiation using a halogen gas or the like. Furthermore, variation in the characteristics of the electrostatic chuck can also be reduced, and hence the electrostatic chuck can be used for a longer period of time in a plasma processing chamber.

1. An electrostatic chuck comprising:
a ceramic dielectric made of a sintered body containing alumina and titanium oxide, with maximum particle size of segregation bodies of titanium compounds being smaller than average particle size of alumina, the ceramic dielectric having a volume resistivity of 10⁸ Ωcm or more and 10¹³ Ωcm or less at room temperature.

2. The electrostatic chuck according to claim 1, wherein the maximum particle size of segregation bodies of titanium compounds is 2 μm or less.

3. The electrostatic chuck according to claim 1, wherein the ceramic dielectric has a bulk density of 3.97 g/cm³ or more.
